(19) United States
(12) Patent Application Publication
(10) Pub. No.: US 2026/0302922 A1
(43) Pub. Date: Oct. 1, 2026

(54) GATE DRIVER CIRCUIT

(71) Applicant: Renesas Design (UK) Limited, Bourne End (GB)

(72) Inventor: Martin Färber, München (DE)

(73) Assignee: Renesas Design (UK) Limited, Bourne End (GB)

(21) Appl. No.: 19/093,736

(22) Filed: Mar. 28, 2025

(51) Int. Cl. H02M 1/08; H03K 5/00; H03K 5/131; H03K 19/0185

(52) U.S. Cl. CPC H02M 1/08; H03K 5/131; H03K 19/018507; H03K 2005/00058

(57) ABSTRACT

A gate driver circuit for a switching converter including a first switch and a second switch, the gate driver circuit including a first switch gate driver configured to receive a first control signal, receive a first delay signal, and provide a first switch gate drive signal to turn on the first switch when the first control signal and the first delay signal are both in a first state, a second switch gate driver configured to receive a second control signal, and provide a second switch gate drive signal to drive the switching operation of the second switch, a first delay generator including a replica second switch gate driver, and a first delay signal generator.

### FIELD

The present disclosure relates to a gate driver circuit. In particular, the present disclosure relates to a gate driver circuit for a switching converter.

### BACKGROUND

It is important for switching converters to commutate currents from one path to another by seamless switching. Ideally one switch is turning off and the other switch takes over the current in the same moment. An overlap where both switches of such a pair are on must be avoided. If two switches are simultaneously in an on state, it may result in the shorting of different low-impedance voltage nodes such as a supply voltage node and a ground node.

There are known methods that generate a significant non-overlap time where the current flow is kept through parasitic diodes. Further known methods use a digital programmable delay between the switch activation signals for the high-side switch and the low-side switch. Further known methods use adaptive deadtime minimization to prevent overlap, but these use complex circuit configurations.

Each of the known methods has one or more of the following disadvantages:
1 Long non-overlapping times leading to high losses and parasitic bipolar effects.
2 High complexity.
3 High current consumption for state detection.
4 Problems in case of fast changes of the load current at the output node.

### SUMMARY

It is desirable to provide a gate driver circuit that mitigates or overcomes one or more of the above-mentioned problems.

According to a first aspect of the disclosure there is provided a gate driver circuit for a switching converter comprising a first switch and a second switch, the gate driver circuit comprising a first switch gate driver configured to receive a first control signal, receive a first delay signal, and provide a first switch gate drive signal to turn on the first switch when the first control signal and the first delay signal are both in a first state, a second switch gate driver configured to receive a second control signal, and provide a second switch gate drive signal to drive the switching operation of the second switch, a first delay generator comprising a replica second switch gate driver, and a first delay signal generator, wherein the replica second switch gate driver is configured to provide a replica second switch gate drive signal to the first delay signal generator, the replica second switch gate drive signal being dependent on the first control signal, and the first delay signal generator is configured to generate the first delay signal that is dependent on the replica second switch gate drive signal.

Optionally, the second switch gate driver and the replica second switch gate driver have substantially similar circuit topologies.

Optionally, the second switch gate driver comprises one or more second side transistors, and the replica second switch gate driver comprises one or more replica second side transistors.

Optionally, the second switch gate driver comprises one or more second side PMOS transistors and the replica second switch gate driver comprises one or more replica second side PMOS transistors, and/or the second switch gate driver comprises one or more second side NMOS transistors and the replica second switch gate driver comprises one or more replica second side NMOS transistors.

Optionally, a second switch driver transistor ratio is provided by a ratio of i) a transistor ratio of one of the one or more second side transistors to a transistor ratio of another of the one or more second side transistors, or ii) a transistor ratio of the second switch to the transistor ratio of one of the one or more second side transistors, a replica second switch driver transistor ratio is provided by a ratio of i) a transistor ratio of one of the one or more replica second side transistors to a transistor ratio of another of the one or more replica second side transistors, or ii) a transistor ratio of a replica second switch to the transistor ratio of one of the one or more replica second side transistors, and the second switch driver transistor ratio and the replica second switch driver transistor ratio are approximately equal.

Optionally, the transistor ratio of the one of the one or more second side transistors is the width to length ratio of the one of the one or more second side transistors, the transistor ratio of the another of the one or more second side transistors is the width to length ratio of the another of the one or more second side transistors, the transistor ratio of the second switch is the width to length ratio of the second switch, the transistor ratio of the one of the one or more replica second side transistors is the width to length ratio of the one of the one or more replica second side transistors, the transistor ratio of the another of the one or more replica second side transistors is the width to length ratio of the another of the one or more replica second side transistors, and the transistor ratio of the replica second switch is the width to length ratio of the replica second switch.

Optionally, the second switch gate driver comprises one or more second side logic gates and the replica second switch gate driver comprises one or more replica second side logic gates that are the same type as the one or more second side logic gates.

Optionally, the second switch gate driver is positioned sufficiently close to the replica second switch gate driver to be subject to a substantially similar operating temperature during operation.

Optionally, the second switch gate driver comprises a first gate driver switch, a second gate driver switch coupled to the first gate driver switch at a second switch gate driver output node, a second switch gate driving signal being provided from the second switch gate driver output node, a first driving circuit for driving the switching of the first gate driver switch, a second driving circuit for driving the switching of the second gate driver switch.

Optionally, the first driving circuit comprises a first buffer circuit and a first NAND gate, and the second driving circuit comprises a second buffer circuit and a third buffer circuit or an AND circuit.

Optionally, the replica second switch gate driver comprises a first delay generator switch, a second delay generator switch coupled to the first delay generator switch at a replica second switch gate driver output node, the replica second switch gate drive signal being provided from the replica second switch gate driver output node, a replica first driving circuit for driving the switching operation of the first delay generator switch, and a replica second driving circuit for driving the switching operation of the second delay generator switch.

Optionally, the replica first driving circuit comprises a second NAND gate, a first inverter circuit, and a second inverter circuit, the replica second driving circuit comprises a third NAND gate, and a third inverter circuit.

Optionally, the gate driver circuit comprises a programmable delay circuit configured to receive a first delay generator switch indicator signal from the replica first driving circuit, apply a delay parameter to the first delay generator switch indicator signal, and provide the first delay generator switch indicator signal, after the delay parameter has been applied, to the replica second driving circuit, wherein the replica second driving circuit is configured to provide a delayed gate driving signal to the second delay generator switch that is dependent on the first control signal and the first delay generator switch indicator signal after the delay parameter has been applied.

Optionally, the programmable delay circuit is configured to receive a configuration signal, the delay parameter being dependent on the configuration signal.

Optionally, the gate driver circuit comprises a first level shifter configured to level shift the first control signal, and a second level shifter configured to provide the configuration signal to the first delay generator to correct for a switch delay resulting from the first level shifter.

Optionally, the first delay signal generator comprises a third delay generator switch, a fourth delay generator switch coupled to the third delay generator switch at a first node, the fourth delay generator switch comprising a fourth delay generator switch gate terminal coupled to the replica second switch gate driver output node, and a delay signal generator buffer circuit comprising a first input terminal coupled to the first node, and a first output terminal for providing the first delay signal.

Optionally, the third delay generator switch is driven by fewer inverter stages than the fourth delay generator switch.

Optionally, the first switch and the fourth delay generator switch have one or more of the same transistor type, and/or approximately equal transistor widths and/or lengths.

Optionally, the gate driver circuit comprises a fourth buffer circuit configured to receive the first control signal and to provide a first replica control signal, and a fourth inverter circuit configured to receive the first replica control signal and to provide a second replica control signal, wherein the replica first driving circuit is configured to receive the second replica control signal, and to drive the switching operation of the first delay generator switch based on the second replica control signal and a second delay generator switch indicator signal.

Optionally, the third delay generator switch comprises a third delay generator switch gate terminal configured to receive the second replica control signal.

Optionally, the first state is an on state.

Optionally, the first switch is a high side switch and the second switch is a low side switch, and/or the first switch is the low side switch and the second switch is the high side switch.

Optionally, the second switch gate driver is configured to receive a second delay signal, and provide the second switch gate drive signal to turn on the second switch when the second control signal and the second delay signal are both in the first state or a second state, the gate driver circuit comprises a second delay generator comprising a replica first switch gate driver, and a second delay signal generator; wherein the replica first switch gate driver is configured to provide a replica first switch gate drive signal to the second delay signal generator, the replica first switch gate drive signal being dependent on the second control signal, and the second delay signal generator is configured to generate the second delay signal that is dependent on the replica first switch gate drive signal.

Optionally, the first switch gate driver and the replica first switch gate driver have substantially similar circuit topologies, and/or the second switch gate driver and the replica second switch gate driver have substantially similar circuit topologies.

Optionally, the first switch gate driver comprises one or more first side transistors and the replica first switch gate driver comprises one or more replica first side transistors, and/or the second switch gate driver comprises one or more second side transistors, and the replica second switch gate driver comprises one or more replica second side transistors.

Optionally, the first switch gate driver comprises one or more first side PMOS transistors and the replica first switch gate driver comprises one or more replica first side PMOS transistors, and/or the first switch gate driver comprises one or more first side NMOS transistors and the replica first switch gate driver comprises one or more replica first side NMOS transistors, and/or the second switch gate driver comprises one or more second side PMOS transistors and the replica second switch gate driver comprises one or more replica second side PMOS transistors, and/or the second switch gate driver comprises one or more second side NMOS transistors and the replica second switch gate driver comprises one or more replica second side NMOS transistors.

Optionally, a first switch driver transistor ratio is provided by a ratio of i) a transistor ratio of one of the one or more first side transistors to a transistor ratio of another of the one or more first side transistors, or ii) a transistor ratio of the first switch to the transistor ratio of one of the one or more first side transistors, a replica first switch driver transistor ratio is provided by a ratio of i) a transistor ratio of one of the one or more replica first side transistors to a transistor ratio of another of the one or more replica first side transistors, or ii) a transistor ratio of a replica first switch to the transistor ratio of one of the one or more replica first side transistors, and the first switch driver transistor ratio and the replica first switch driver transistor ratio are approximately equal, and/or a second switch driver transistor ratio is provided by a ratio of i) a transistor ratio of one of the one or more second side transistors to a transistor ratio of another of the one or more second side transistors, or ii) a transistor ratio of the second switch to the transistor ratio of one of the one or more second side transistors, a replica second switch driver transistor ratio is provided by a ratio of i) a transistor ratio of one of the one or more replica second side transistors to a transistor ratio of another of the one or more replica second side transistors, or ii) a transistor ratio of a replica second switch to the transistor ratio of one of the one or more replica second side transistors, and the second switch driver transistor ratio and the replica second switch driver transistor ratio are approximately equal.

Optionally, the transistor ratio of the one of the one or more first side transistors is the width to length ratio of the one of the one or more first side transistors, the transistor ratio of the another of the one or more first side transistors is the width to length ratio of the another of the one or more first side transistors, the transistor ratio of the first switch is the width to length ratio of the first switch, the transistor ratio of the one of the one or more replica first side transistors is the width to length ratio of the one of the one or more replica first side transistors, the transistor ratio of the another of the one or more replica first side transistors is the width to length ratio of the another of the one or more replica first side transistors, and the transistor ratio of the replica first switch is the width to length ratio of the replica first switch, and/or the transistor ratio of the one of the one or more second side transistors is the width to length ratio of the one of the one or more second side transistors, the transistor ratio of the another of the one or more second side transistors is the width to length ratio of the another of the one or more second side transistors, the transistor ratio of the second switch is the width to length ratio of the second switch, the transistor ratio of the one of the one or more replica second side transistors is the width to length ratio of the one of the one or more replica second side transistors, the transistor ratio of the another of the one or more replica second side transistors is the width to length ratio of the another of the one or more replica second side transistors, and the transistor ratio of the replica second switch is the width to length ratio of the replica second switch.

Optionally, the first switch gate driver comprises one or more first side logic gates and the replica first switch gate driver comprises one or more replica first side logic gates that are the same type as the one or more first side logic gates, and/or the second switch gate driver comprises one or more second side logic gates and the replica second switch gate driver comprises one or more replica second side logic gates that are the same type as the one or more second side logic gates.

Optionally, the first switch gate driver is positioned sufficiently close to the replica first switch gate driver to be subject to a substantially similar operating temperature during operation, and/or the second switch gate driver is positioned sufficiently close to the replica second switch gate driver to be subject to a substantially similar operating temperature during operation.

According to a second aspect of the disclosure there is provided a method of providing a gate driver circuit for a switching converter comprising a first switch and a second switch, the gate driver circuit comprising a first switch gate driver configured to receive a first control signal, receive a first delay signal, and provide a first switch gate drive signal to turn on the first switch when the first control signal and the first delay signal are both in a first state, a second switch gate driver configured to receive a second control signal, and provide a second switch gate drive signal to drive the switching operation of the second switch, a first delay generator comprising a replica second switch gate driver, and a first delay signal generator, wherein the replica second switch gate driver is configured to provide a replica second switch gate drive signal to the first delay signal generator, the replica second switch gate drive signal being dependent on the first control signal, and the first delay signal generator is configured to generate the first delay signal that is dependent on the replica second switch gate drive signal.

It will be appreciated that the method of the second aspect may include using and/or providing features set out in relation to the first aspect and may include other features as described herein.

### BRIEF DESCRIPTION OF THE DRAWINGS

The disclosure is described in further detail below by way of example and with reference to the accompanying drawings, in which:

FIG. 1A is a schematic of a gate driver circuit for a switching converter in accordance with a first embodiment of the present disclosure, FIG. 1B is a timing graph showing example waveforms, FIG. 1C is a schematic of a specific embodiment of the gate driver circuit in accordance with a second embodiment of the present disclosure, FIG. 1D is a schematic of specific implementations of the gate drivers and the replica gate drivers as may be implemented in the gate driver circuit of FIG. 1C;

FIG. 2A is a schematic of a portion of a specific implementation of the gate driver circuit and the switching converter in accordance with a third embodiment of the present disclosure, FIG. 2B is a schematic of a further specific implementation of the gate driver circuit and the switching converter in accordance with a fourth embodiment of the present disclosure, FIG. 2C is a schematic of a specific embodiment of the second switch gate driver of FIG. 2B, in accordance with a fifth embodiment of the present disclosure, FIG. 2D is a schematic of a specific embodiment of the delay generator of FIG. 2B in accordance with a sixth embodiment of the present disclosure;

FIG. 3 is a schematic of a specific implementation of the delay generator in accordance with a seventh embodiment of the present disclosure;

FIG. 4 is a schematic of a specific implementation of the gate driver circuit and the switching converter in accordance with an eighth embodiment of the present disclosure;

FIG. 5 is a schematic of a specific implementation of the high side power stage in accordance with a ninth embodiment of the present disclosure; and

FIG. 6A is a table of results for Monte Carlo simulations of the circuit of FIG. 4, having varied parameters in Monte Carlo for non-overlapping, FIG. 6B is a table of results for Monte Carlo simulations of the circuit of FIG. 4 having matching of delays, non-overlap time in the Monte Carlo simulation, FIG. 6C is a table of results for Monte Carlo simulations of the circuit of FIG. 4 having absolute delays in the Monte Carlo simulation.

### DETAILED DESCRIPTION

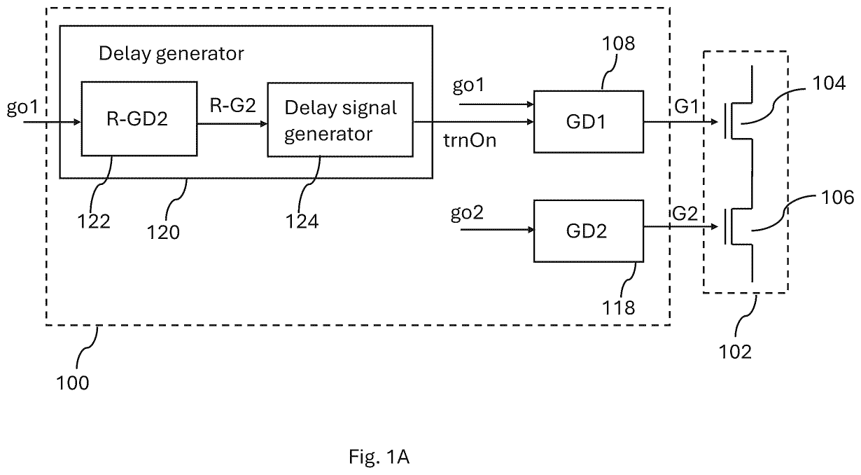

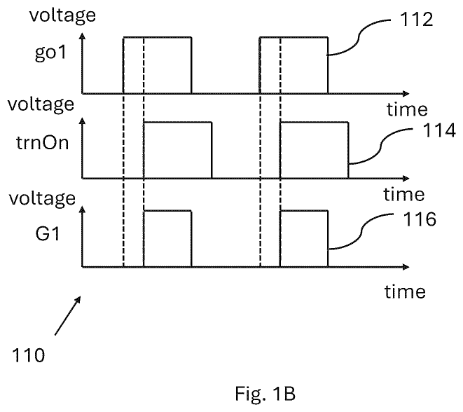

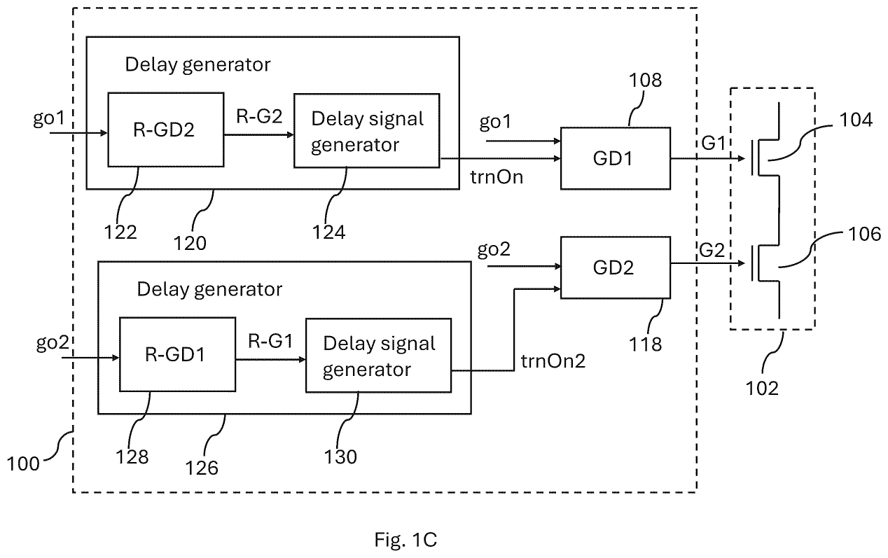

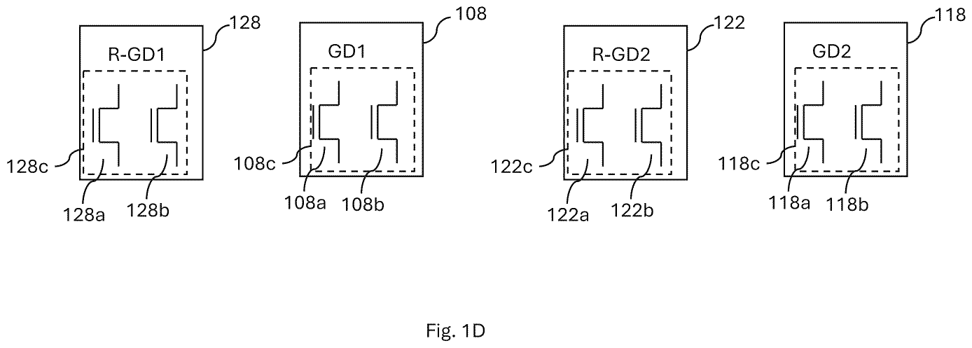

FIG. 1A is a schematic of a gate driver circuit 100 for a switching converter 102 comprising a first switch 104 and a second switch 106 in accordance with a first embodiment of the present disclosure.

The switching converter 102 may, for example, be a buck converter, a boost converter or a buck boost converter. The switching converter 102 may comprise an energy storage element (not shown) such as an inductor. The switches 104, 106 may be referred to as power switches, and may each comprise a transistor. The switches 104, 106 may be coupled in series between two supply voltage terminals. During operation, the switches 104, 106 may be operated to periodically couple and decouple the energy storage element from the supply voltage terminals, to provide a regulated output voltage. The first switch 104 may be a high side switch or a low side switch and the second switch 106 may be the other of a high side switch or a low side switch.

Each of the switches 104, 106 may comprise an NMOS transistor and/or a PMOS transistor.

In a specific embodiment, when creating a power switch by using a “NMOS transistor and a PMOS transistor” one gate driver would have a negative supply voltage referred to the source of the p-MOS and the other driver would have a positive supply voltage referred to the n-MOS.

The gate driver circuit 100 comprises a first switch gate driver 108 (also labelled “GD1”) configured to receive a control signal go1 and a delay signal trnOn. The first switch gate driver 108 is configured to provide a gate drive signal G1 to turn on the first switch 104 when both the control signal go1 and the delay signal trnOn are in a first state.

FIG. 1B is a timing graph 110 showing example waveforms for the control signal go1 (a trace 112), the delay signal trnOn (a trace 114) and the gate drive signal G1 (a trace 116).

The control signal go1 may be a digital signal provided from a controller (not shown). During operation, the control signal go1 may transition between two states. As shown in FIG. 1B, the control signal go1 transitions between a high state and a low state, where the high state may be referred to as an “on state” and the low state may be referred to as an “off state”. The delay signal trnOn also transitions between two states. The first state may be the on state and a second state may be the off state.

The gate drive signal G1 is used to control the switching operation of the first switch 104, such that the gate drive signal G1 being in a high state may turn the switch “on” to permit current flow, and the gate drive signal G1 being in a low state may turn the switch “off” to prevent current flow.

The delay signal trnOn applies a delay before permitting the turning on of the first switch 104, thereby preventing both switches 104, 106 from being in an on state simultaneously. During operation, the first switch gate driver 108 provides the gate drive signal G1 to turn the first switch on 104 when both the control signal go1 and the delay signal trnOn are in the high state.

It will be appreciated that in a further embodiment, during operation, the first switch gate driver 108 may provide the gate drive signal G1 to turn the first switch on 104 when both the control signal go1 and the delay signal trnOn are in the low state. It will be appreciated that in a further embodiment, the first switch 104 may be enabled when the gate drive signal G1 is in a low state.

It will be appreciated that the graph of FIG. 1B is for illustrative purposes only for an idealised system. For a practical implementation, the power switches 104, 106 have a high gate capacitance, which means that the gate voltages edges would have a longer period of time but not with infinite slope. Notably the falling edge of the gate voltage G1 should not end before the turnOn delay ends. In a symmetric circuit where the gate drivers, delays and power devices of both switches are the same, the turn on delay would match the falling edge of the gate voltage (neglecting the following two facts: a) the gate voltage might be between 0V and the threshold when the device is off and b) when the turn on signal rises the gate does not rise immediately as there is some combinatorial logic needed and the gate driver-having multiple stages in most cases-adds a little further delay.)

The gate driver circuit 100 further comprises a second switch gate driver 118 configured to receive a control signal go2 and provide a gate drive signal G2 to drive the switching operation of the second switch 106.

The control signal go2 may be a digital signal provided from a controller (not shown). During operation, the control signal go2 may transition between two states, for example, as shown in relation to the control signal go1. The control signal go2 may be an inverted control signal go1. The gate driver circuit 100 further comprises a delay generator 120 for generating the delay signal trnOn. The delay generator 120 comprises a replica second switch gate driver 122 and a delay signal generator 124.

During operation, the replica second switch gate driver 122 (also labelled “R-GD2”) provides a replica second switch gate drive signal R-G2 to the delay signal generator 124. The replica gate drive signal R-G2 is dependent on the control signal go1.

The delay signal generator 124 is configured to generate the delay signal trnOn that is dependent on the replica second switch gate drive signal R-G2.

In the present example, the control signal go1 is shown as being provided to the replica second switch gate driver 122 and the first switch gate driver 108 to illustrate the dependency of each of the replica switch gate drive signal R-G2 and the gate drive signal G1 on the control signal go1. However, it will be appreciated that the control signal go1 may be processed, altered, or used to generate an intermediate signal prior to being used to generate one or both of the signals R-G2, G1. For example, the replica gate drive signal R-G2 may be generated using an inverted control signal go1, with the gate drive signal G1 being generated using a non-inverted control signal go1.

The replica second switch gate driver 122 is a replica of the second switch gate driver 118. By “replica” it is meant that the replica gate driver is designed to exhibit a sufficiently similar performance to the original gate driver (which may be referred to as the “corresponding” gate driver), such that the replica gate driver may be used to extract information on the performance of the original gate driver. Specifically, the use of the replica second switch gate driver 122 means that information on the required delay to prevent overlap of the on-time of the switches 104, 106 can be acquired and used to generate a suitable delay signal trnOn to prevent simultaneous on-time of the switches 104, 106.

Information on the performance of the second switch gate driver 118 is provided to the delay signal generator 124 by the replica gate drive signal R-G2.

For example, the replica second switch gate drive signal R-G2 may indicate when the second switch 106 is in the second state. The second state may be an off state.

In specific embodiments, to function as a replica gate driver, the replica second switch gate driver 122 may receive the same supply voltage as the second switch gate driver 118.

In specific embodiments, to function as a replica gate driver, the second switch gate driver 118 and the replica second switch gate driver 122 may have substantially similar circuit topologies.

Substantially similar circuit topologies means that the circuits use the same, or functionally similar, components with a same, or functionally similar, circuit layout in a physical implementation, for example when manufactured as part of the same integrated circuit.

In specific embodiments, to function as replica gate drivers, and when implemented in a physical circuit, for example as part of an integrated circuit, the second switch gate driver 118 may be positioned sufficiently close to the replica second switch gate driver 122 such that they are both subject to a substantially similar operating temperature during operation.

In summary, to provide good matching of the timing of the replica gate driver to the timing in its corresponding gate driver, they may have one or more of the following:
similar transistor types
similar topologies (for examples, inverters, NAND and NOR gates)
similar supply voltages
similar operating temperature (by placing components of the replica gate driver and the corresponding gate driver close to each other)

“Good matching” of the replica gate driver, and its corresponding gate driver, can enable the delay produced by the gate driver to be present in the replica gate driver, which can then be used to correct for the delay.

FIG. 1C is a schematic of a specific embodiment of the gate driver circuit 100 in accordance with a second embodiment of the present disclosure.

In the present embodiment, the gate driver circuit 100 comprises a delay generator 126 for the second switch 106. It will be appreciated that the delay generator 126 and the second switch gate driver 118 may function substantially as described for the delay generator 120 and the first switch gate driver 108, respectively, in accordance with the understanding of the skilled person. In further embodiments, the delay generator 126 may include features described in relation to the delay generator 120.

The second switch gate driver 118 is configured to receive a delay signal trnOn2 and to provide the second switch gate drive signal G2 to turn on the second switch 106 when the control signal go2 and the delay signal trnOn2 are both in the first state or a second state. The first state may, for example, be the on state and may be the same state as described in relation to the operation of the first switch 104. The second state may be a state that is distinct from the first state as described in relation to the operation of the first switch 104.

The delay generator 126 is for generating the delay signal trnOn2. The delay generator 126 comprises a replica first switch gate driver 128 and a delay signal generator 130.

During operation, the replica first switch gate driver 128 (also labelled “R-G1”) provides a replica first switch gate drive signal R-G1 to the delay signal generator 130. The replica gate drive signal R-G1 is dependent on the control signal go2.

The delay signal generator 130 is configured to generate the delay signal trnOn2 that is dependent on the replica first switch gate drive signal R-G1.

The replica first switch gate driver 128 is a replica of the first switch gate driver 108. The use of the replica first switch gate driver 128 means that information on the required delay to prevent overlap of the on-time of the switches 104, 106 can be acquired and used to generate a suitable delay signal trnOn2 to prevent simultaneous on-time of the switches 104, 106.

Information on the performance of the first switch gate driver 108 is provided to the delay signal generator 130 by the replica gate drive signal R-G1.

For example, the replica first switch gate drive signal R-G1 may indicate when the first switch 104 is in the second state. The second state may be an off state.

In specific embodiments, to function as a replica gate driver, the replica first switch gate driver 128 may receive the same supply voltage as the first switch gate driver 108.

In specific embodiments, to function as a replica gate driver, the first switch gate driver 108 and the replica first switch gate driver 128 may have substantially similar circuit topologies.

FIG. 1D is a schematic of specific implementations of the gate drivers 108, 118 and the replica gate drivers 122, 128.

The specific implementation of the gate driver 118 and the replica gate driver 122 may be implemented in the gate driver circuit 100 of FIG. 1A.

The specific implementations of one or both of the gate drivers 108, 118 and one or both the replica gate drivers 122, 128 may be implemented in the gate driver circuit 100 of FIG. 1C.

The first switch gate driver 108 may comprise one or more first side transistors 108a, 108b and the replica first switch gate driver 128 may comprise one or more replica first side transistors 128a, 128b.

Each of the first side transistors 108a, 108b may comprise a PMOS transistor or an NMOS transistor.

Each of the replica first side transistors 128a, 128b may comprise a PMOS transistor or an NMOS transistor.

The second switch gate driver 118 may comprise one or more second side transistors 118a, 118b and the replica second switch gate driver 122 may comprise one or more replica second side transistors 122a, 122b.

Each of the second side transistors 118a, 118b may comprise a PMOS transistor or an NMOS transistor.

Each of the replica second side transistors 122a, 122b may comprise a PMOS transistor or an NMOS transistor.

A first switch driver transistor ratio may be provided by a ratio of a transistor ratio of one of the first side transistors 108a to a transistor ratio of another of the first side transistors 108b.

Alternatively, the first switch driver transistor ratio may be provided by the transistor ratio of one of the one or more first side transistors 108a to a transistor ratio of the first switch 104.

A replica first switch driver transistor ratio may be provided by a ratio of a transistor ratio of one of the replica first side transistors 128a to a transistor ratio of another of the replica first side transistors 128b.

Alternatively, the replica first switch driver transistor ratio may be provided by a transistor ratio of one of the one or more replica first side transistors 128a to a transistor ratio of a replica first switch (not shown). The replica first switch may be a replica of the first switch 104.

The first switch driver transistor ratio and the replica first switch driver transistor ratio may be approximately equal.

A second switch driver transistor ratio may be provided by a ratio of a transistor ratio of one of the second side transistors 118a to a transistor ratio of another of the second side transistors 118b.

Alternatively, the second switch driver transistor ratio may be provided by the transistor ratio of one of the one or more second side transistors 118b to a transistor ratio of the second switch 106.

A replica second switch driver transistor ratio may be provided by a ratio of a transistor ratio of one of the replica second side transistors 122a to a transistor ratio of another of the replica second side transistors 122b.

Alternatively, the replica second switch driver transistor ratio may be provided by the transistor ratio of one of the one or more replica second side transistors 122a to a transistor ratio of a replica second switch (not shown). The replica second switch may be a replica of the second switch 106.

The second switch driver transistor ratio and the replica second switch driver transistor ratio may be approximately equal.

By having the first switch driver transistor ratio of the first switch gate driver 108 as approximately equal to the replica first switch driver transistor ratio of the replica first switch gate driver 128, the replica first switch gate driver 128 may function as a “replica” of the first switch gate driver 108, as discussed previously.

Similarly, by having the second switch driver transistor ratio of the second switch gate driver 118 as approximately equal to the replica second switch driver transistor ratio of the replica second switch gate driver 122, the replica second switch gate driver 122 may function as a “replica” of the second switch gate driver 118, as discussed previously.

The transistor ratio of a transistor may be defined as the width to length ratio of the transistor.

The width to length ratio is a well-known parameter in circuit design, where the width refers to the physical width of the transistor gate and the length refers to the physical length of the transistor gate. The width to length ratio can have an impact of the properties and performance of the transistor.

The first switch gate driver 108 may comprise one or more first side logic gates 108c, which may comprise the transistors 108a, 108b. The replica first switch gate driver 128 may comprise one or more replica first side logic gates 128c, which may comprise the transistors 128a, 128b. The one or more first side logic gates 108c may be the same type as the one or more replica first side logic gates 128c.

The second switch gate driver 118 may comprise one or more second side logic gates 118c, which may comprise the transistors 118a, 118b. The replica second switch gate driver 122 may comprise one or more replica second side logic gates 122c, which may comprise the transistors 122a, 122b. The one or more second side logic gates 118c may be the same type as the one or more replica second side logic gates 122c.

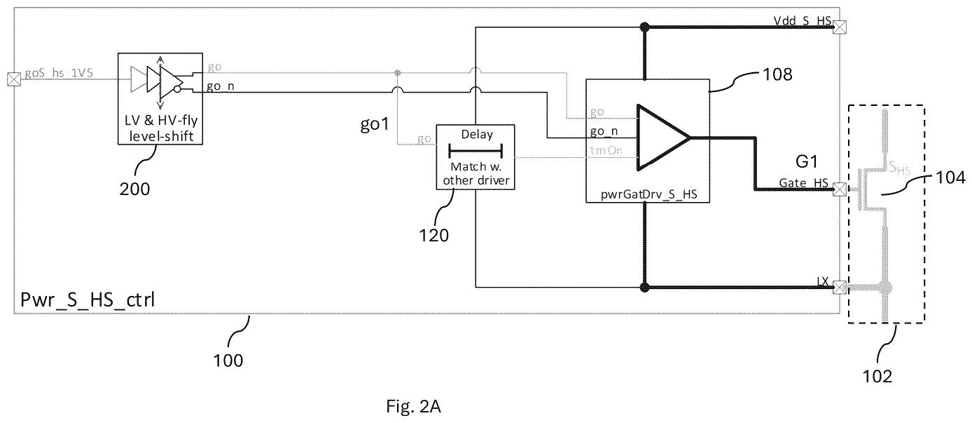

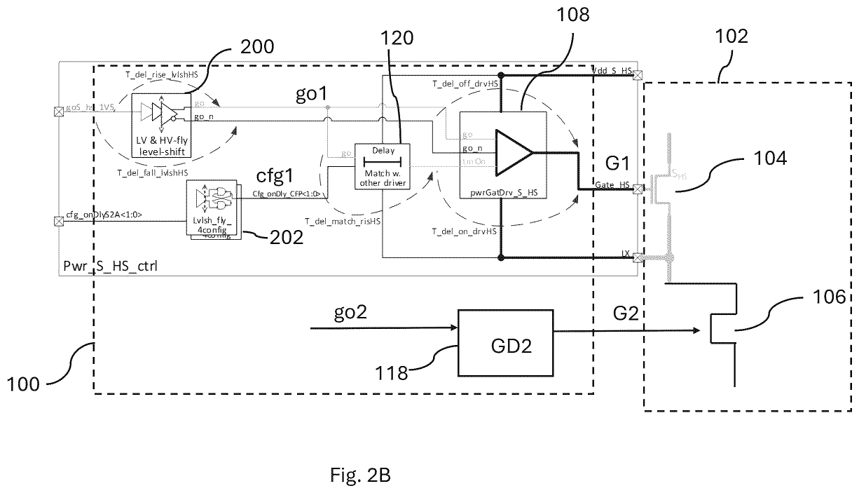

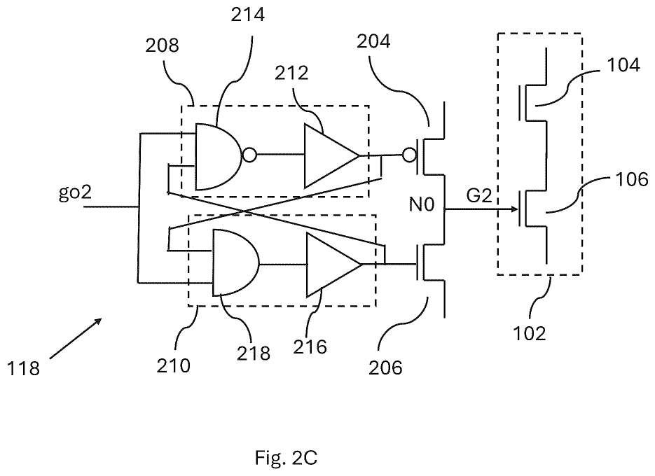

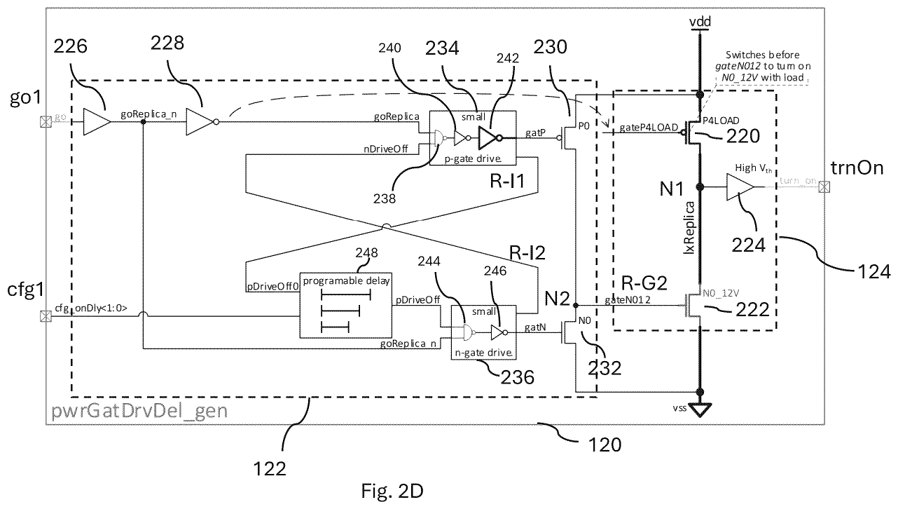

FIG. 2A is a schematic of a portion of a specific implementation of the gate driver circuit 100 and the switching converter 102 of FIG. 1A in accordance with a third embodiment of the present disclosure. In the present embodiment, the gate driver circuit 100 comprises a level shifter 200 configured to level shift the control signal go1. Level shifting refers to the process of shifting the voltage level of a signal to an appropriate level for use with subsequent circuitry.

FIG. 2A shows the principle of gate control circuitry at the example of a high side switch of a power inverter and includes the level-shifter 200. Here the first switch gate driver 108 turns on the gate of the switch 104 (at a node Gate_HS) only if the signals “go” (being the control signal go1) and the delay signal trnOn are high. The turn off starts at the rising edge of “go_n” which is an inverted control signal go1.

FIG. 2B is a schematic of a further specific implementation of the gate driver circuit 100 and the switching converter 102 of FIG. 1A in accordance with a fourth embodiment of the present disclosure. In the present embodiment, the gate driver circuit 100 comprises a level shifter 202 for the delay unit 120 configured to provide a configuration signal cfg1 to the delay generator 120 which may be used by the delay generator 120 to correct for a switch delay resulting from the level shifter 200. Optionally multiple level shifters and a signal bus might be used for delay configuration.

FIG. 2C is a schematic of a specific embodiment of the second switch gate driver 118 of the gate driver circuit 100 of FIG. 2B, in accordance with a fifth embodiment of the present disclosure.

FIG. 2C is a schematic of a specific implementation of the second switch gate driver 118 that may be used for any of the embodiments described herein, in accordance with the understanding of the skilled person. It will be appreciated that in further embodiments, one or both of the first and second switch gate drivers 108, 118 may be implemented as shown for the second switch gate driver 118 of FIG. 2C.

The second switch gate driver 118 may comprise gate driver switches 204, 206 that are coupled together at an output node N0. During operation, the gate driving signal G2 for the second switch 106 is provided from the output node N0.

The second switch gate driver 118 further comprises driving circuits 208, 210. During operation, the driving circuit 208 drives the switching of the gate driver switch 204 and the driving circuit 210 drives the switching of the gate driver switch 206.

The driving circuit 208 may comprise a buffer circuit 212 and a NAND gate 214. The driving circuit 210 may comprise a buffer circuit 216 and an AND circuit 218. The buffer circuit 216 may comprise two inverters.

FIG. 2D is a schematic of a specific embodiment of the delay generator 120 of the gate driver circuit 100 of FIG. 2B, in accordance with a sixth embodiment of the present disclosure.

FIG. 2D is a schematic of a specific implementation of the delay generator 120 that may be used for any of the embodiments described herein, in accordance with the understanding of the skilled person. It will be appreciated that in further embodiments, one or both of the delay generators 120, 126 may be implemented as shown for the delay generator 120 of FIG. 2D.

In the present embodiment, the delay signal generator 124 further comprises a delay generator switch 220 and a delay generator switch 222, coupled together at a node N1. A gate terminal of the delay generator switch 222 is coupled to a node N2.

The delay signal generator 124 further comprises a buffer circuit 224 having an input coupled to the node N1 and configured to provide the delay signal trnOn at its output.

The first switch 104 and the delay generator switch 222 may be of the same transistor type (for example PMOS or NMOS) and/or may have approximately equal transistor widths and/or lengths whereas a scale-factor is applied. In a specific embodiment, the power switch 104 and the replica switch 222 do not have the same width. The replica is preferably much smaller (e.g. by a factor 100). The length may have the same (minimum) value.

The delay generator 120 further comprises a buffer circuit 226 configured to receive the control signal go1 and to provide a replica control signal goReplica_n. The delay generator 120 further comprises an inverter circuit 228 configured to receive the replica control signal goReplica_n and to provide a replica control signal goReplica.

The replica second switch gate driver 122 comprises a delay generator switch 230 and a delay generator switch 232. The delay generator switches 230, 232 are coupled at the node N2. During operation, the replica second switch gate drive signal R-G2 is provided from the node N2.

The delay signal generator 120 generates the delayed trnOn signal based on the transition of the voltage at the node N2.

The replica second switch gate driver 122 further comprises a replica first driving circuit 234 for driving the switching operation of the delay generator switch 230, and a replica second driving circuit 236 for driving the switching operation of the delay generator switch 232.

During operation, the replica first driving circuit 234 provides a gate drive signal gatP to drive the switching operation of the delay generator switch 230. The gate drive signal gatP is dependent on the control signal go1 and an indicator signal R-I2.

During operation, the replica second driving circuit 236 provides a gate drive signal gatN to drive the switching operation of the delay generator switch 232. The gate drive signal gatN is dependent on the control signal go1 and an indicator signal R-I1.

The indicator signal R-I1 indicates when the replica first driving circuit 234 is controlling the delay generator switch 230 to be in an off state. The indicator signal R-I2 indicates when the replica second driving circuit 236 is controlling the delay generator switch 232 to be in an off state.

The indicator signals R-I1 an R-I2 may be non-overlap signals which may be present inside the gate drivers 108, 118 as well. In the case of big power switches it is preferable that the last stages of the gate drivers also operate without overlap.

It can be observed that the specific implementation of the replica second switch gate driver 122 of FIG. 2D shares a substantially similar circuit design to the second switch gate driver 118 of FIG. 2C, such that the replica second switch gate driver 122 functions as a “replica” of the second switch gate driver 118.

The replica first driving circuit 234 of the present embodiment comprises a NAND gate 238 and inverter circuit 240, 242. The replica second driving circuit 236 of the present embodiment comprises a NAND gate 244 and an inverter circuit 246.

The replica first driving circuit 234 is configured to receive the replica control signal goReplica, the gate drive signal gatP being dependent on the replica control signal goReplica and the indicator signal R_I2.

The replica second driving circuit 236 is configured to receive the replica control signal goReplica_n, the gate drive signal gatN being dependent on the replica control signal goReplica_n and the indicator signal R-I1.

The delay generator switch 220 is configured to receive the replica control signal goReplica (also labelled gateP4LOAD) at its gate terminal.

The delay generator switch 220 may be driven by fewer inverter stages than the delay generator switch 222.

The replica second gate driver 122 further comprises a programmable delay circuit 248 configured to receive the indicator signal R-I1 and apply a delay parameter to the indicator signal R-I1. The programmable delay circuit 248 is further configured to provide the indicator signal R-I1 after the delay parameter has been applied to the replica second driving circuit 236, the gate drive signal gatN being dependent on the control signal go1 and the indicator signal R-I1 after application of the delay parameter. The delay parameter may be set by the configuration signal cfg1 which may, for example, be provided by a user to calibrate the operation of the delay generator 120.

In case that a gate driver circuit 100 has other blocks like logic gates etc., which generate additional delays, the delay generator 120 preferably compensates for the delay in the turn-off path minus the delay in the turn-on path. Timing mismatches between the edges of the go signals of the two switches 104, 106 may be compensated by logic cells matching the ones generating the go signals at the inputs of the two power-switch blocks for high- and low-side, and as provided by the use of replica gate drivers 122, 128.

A more detailed look into the sub-blocks of such a gate driver circuit 100 shows that the delay generator 120 preferably compensate for the following delay mismatch contributors:
Level-shifter: Ddly_lvlsh=T_del_fall_lvlshLS-T_del_rise_lvlshHS

For the level shifters only the delay difference must be compensated. If symmetrical level-shifter delays can be achieved no delay compensation is needed.
Gate driver: Ddly_gatDrv=T_del_off_drvLS-T_del_on_drvHS

For the gate drivers the turn-off delay ends when the low side switch gate voltage is below its threshold and the turn on delay of the high-side switch ends when the (turn-on) threshold of this switch is reached.

The delay mismatch contributors may, for example, be compensated for by using the programmable delay circuit 248.

To compensate for unexpected delay variations, the configurability of the delay cell is provided by the configuration signal cfg1. For example, a range may be provided by 2 configuration bits.

In the present embodiment of the delay generator 120 all logic gates are built with the same transistor types as the logic and the driver stages in the main path. Preferably minimum length devices were used wherever possible. In specific embodiments, preferably the switches 104, 106 use minimum length devices.

In the present embodiment, the switch 104 is a 12V-power transistor in the high-side part of the inverter that, during operation, is turned on and off with a permanent load current (imposed by an inductance). Also the delay generator switch 220, being the delay-generating transistor corresponding to the switch 104, is turned on with a load current provided by P4LOAD. The switch 104 is turning on just before the delay generator switch 220 turns off as the gate of the switch 104 is derived from a signal with less inverter stages as the gate of the delay generator switch 220.

Specific embodiments of the delay signal generator 120 can be used to reduce the non-overlap time between the turn off of one switch (for example the switch 106) for coupling to a node, and the turn-on of another switch (for example the switch 104) for coupling to the node. During operation, the delay signal generator 120 may effectively synchronise the edges of the “go signals” of both switches (being the control signals go1, go2). This may be achieved by generating a delay with good matching to the turn-off delay in the corresponding gate driving circuitry by using a simplified “replica” driver circuit that uses similar devices/circuits to the corresponding gate driver circuitry.

In specific embodiments, the delay provided by the delay signal generator 120 may be adjusted, for example reduced, to compensate for additional delays in the turn-on path. For example, adjustment of the delay may be controlled by the programmable delay circuit 248.

In summary, embodiments of the delay signal generator 120 may be used to predict the delay needed to turn-off a power-switch and to add a part of this delay into the turn-on path, such that the gate voltage reaches the threshold when the other switch is off or more precisely when its gate voltage is below the threshold.

Returning to FIG. 2C, in a practical implementation, the gate drivers 108, 118 will use minimum length transistors (e.g. 0.5 μm long) with a high width to make the driver strong enough.

Higher gate length will increase the gate capacitance and thus the loss and the delay will grow. Thus, a gate driver n-MOS width w=1000 μm and length l=0.5 μm (for example for the gate driver switch 206 in FIG. 2C) and a p-MOS with width w=1500 μm (for example, the gate driver switch 204 in FIG. 2C) could be used to drive a power transistor (being the switch 106) with a width of 100 mm. p-MOS transistors are typically weaker than n-MOS transistors.

In summary, the w/l ratio of the gate driver switch 206 would be 2000; the w/l ratio of the gate driver switch 204 would be 3000; and the w/l ratio of the switch 106 would be 200,000.

Therefore, in the present example, the second switch driver transistor ratio between the switch 106 and the gate driver switch 206 is 100, and the second switch driver transistor ratio between the switch 106 and the gate driver switch 204 is 67. These are ratios for the last stage of the gate driver 118 and the power device 106.

Returning to FIG. 2D, to generate a matching last stage of the inverter in the replica second switch gate driver 122 (which may be a factor of 1000 smaller the gate driver 118) we could choose a w/l ratio of 1 μm/0.5 μm for the n-MOS (the delay generator switch 232) and a w/l ratio of 1.5 μm/0.5 μm for the p-MOS (the delay generator switch 230). Then we could choose a replica pass-device (the node N1 or the delay generator switch 222) width to be 100 μm. The delay generator switch 222 may be a replica of the switch 106 and may be referred to as a “replica second switch”.

In summary, the w/l ratio of the delay generator switch 232 would be 2; the w/l ratio of the delay generator switch 230 would be 3; and the w/l ratio of the delay generator switch 222 would be 200.

Therefore, in the present example, the replica second switch driver transistor ratio between the switch 222 and the switch 232 is 100, and the replica second switch driver transistor ratio between the switch 222 and the switch 230 is 67.

Thus both timings would match, or more precisely, the 1.0 μm wide n-MOS needs the same time to discharge the gate of the 100 μm wide n-MOS in the replica gate driver 122 as the 1000 μm wide n-MOS for the gate of the 100 mm wide n-MOS pass device.

Therefore in both cases, the second switch driver transistor ratio and the replica second switch driver transistor ratios are equal, such that the replica second switch gate driver 122 may function as a replica of the second switch gate driver 118.

Preferably, this relationship should be used for all stages of a gate driver with a topology according to FIG. 2C and for the replica gate driver which should have again the topology of FIG. 2C. For example, we could choose a factor 3 between the inverter stages driving the device 206 (with only n-MOS sizes being provided in this example):

In buffer circuit 216 which may comprise two inverters:
Width of a transistor N1, N1=33.33 μm,
Width of a transistor N0,_N0=11.11 μm,

In the AND circuit 218:
Width of a transistor N1, N1=3.7 μm
Width of a transistor N0, N0=1.23 μm

For the replica structures the same stages would have the following sizes:

Replica of the buffer circuit 216:
Width of a transistor N1, N1=0.33 μm,
Width of a transistor N0, N0=0.11 μm,

Replica of the AND circuit 218:
Width of a transistor N1, N1=0.037 μm
Width of a transistor N0, N0=0.0123 μm

It will be appreciated that manufacturing transistors with a width of only slightly above 1 nm may be challenging, in which case equivalent functionality may be provided using longer or staggered devices, or using the additional delay which might be introduced by the configurability of the replica.

The elements 214 and 212 could have similar scale factors between the stages. So, these scale-factors of 3, 67 and 100 in the example above determine the delay of the power train and the replica train.

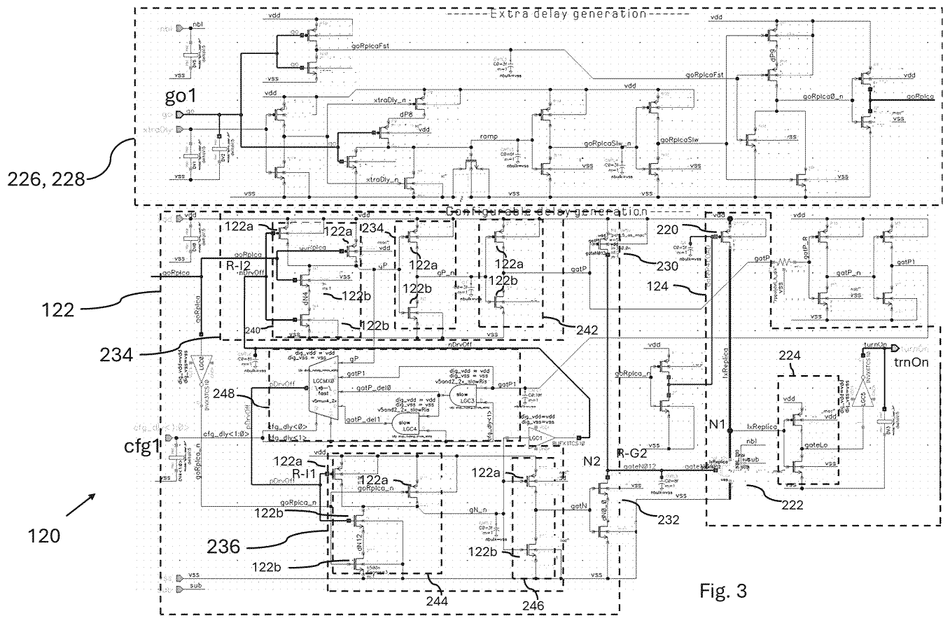

FIG. 3 is a schematic of a specific implementation of the delay generator 120 in accordance with a seventh embodiment of the present disclosure.

In the present embodiment, the delay generator 120 does not have elements to compensate for delta-delays in the level-shifters 200, 202. The level-shifters 200, 202 have a low delay variation even if the voltage between the quiet ground and the one of the flying ground (here LX) changes.

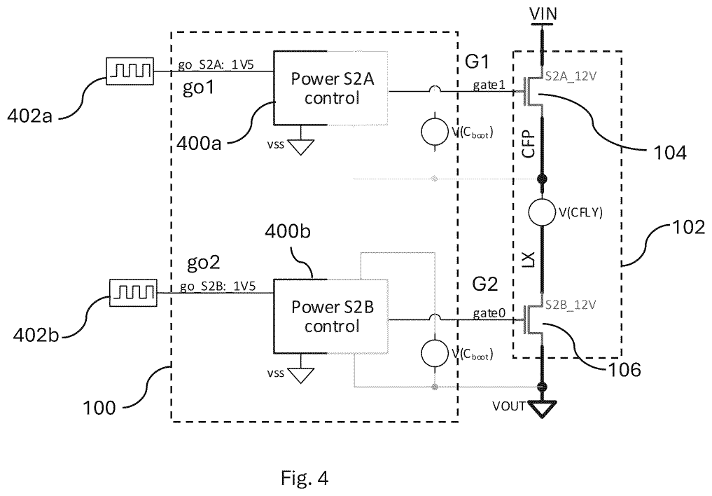

FIG. 4 is a schematic of a specific implementation of the gate driver circuit 100 and the switching converter 102 in accordance with an eighth embodiment of the present disclosure.

The gate driver circuit 100 comprises a high side power stage 400a which may comprise the delay generator 120 and the first switch gate driver 108, such as is shown in FIG. 2B.

The gate driver circuit 100 comprises a low side power stage 400b which may comprise the delay generator 126 and the second switch gate driver 118, such as is shown in FIG. 2B.

It will be appreciated that in further embodiments, the switching converter may be implemented as a multi-level converter (for example, comprising five power switches), with each switch being driven by a power stage having a delay generator in accordance with any of the embodiments described herein, and adapted for multi-level conversion, in accordance with the understanding of the skilled person.

The pair of switches 104, 106 of FIG. 4 was investigated in a simplified test-bench with two switches and an ideal voltage source representing the capacitance “CFLY” which sits between the two switches 104, 106. FIG. 4 is a schematic of a simplified test bench. The two clock generators 402a, 402b here provide the go signals go1, go2 with opposite phases, where the edges are precisely aligned. The two voltage sources “V(Cboot)” provide identical supply voltages. For low and high side switches the input domain is connected to 0V-ground potential “vss”.

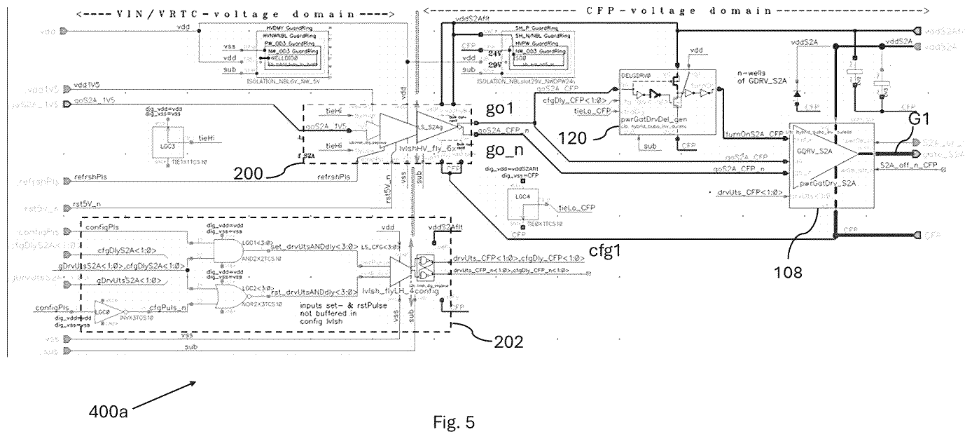

FIG. 5 is a schematic of a specific implementation of the high side power stage 400a in accordance with a ninth embodiment of the present disclosure.

It will be appreciated that the term “test bench” is well known in electronic circuit design and used to describe a simulation environment. Simulations were performed in relation to the circuit schematic of FIG. 4 using the implementation shown in FIG. 5, using practical and physically implementable circuit parameters in accordance with the understanding of the skilled person.

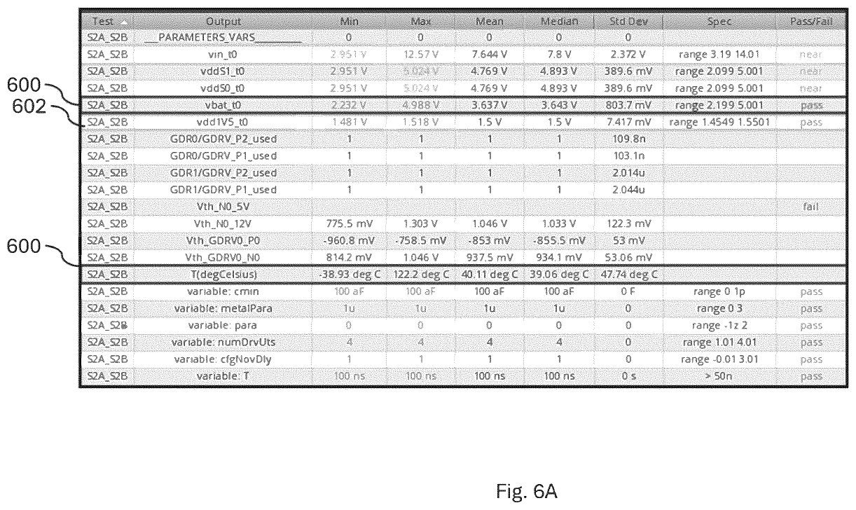

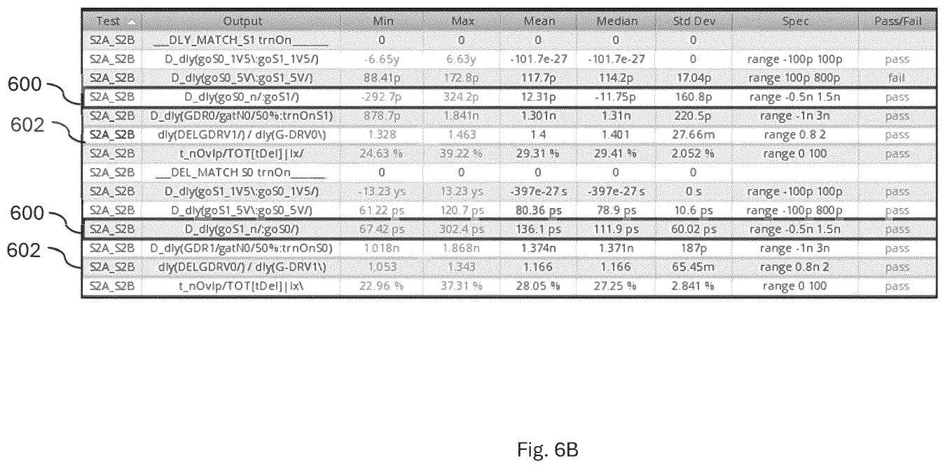

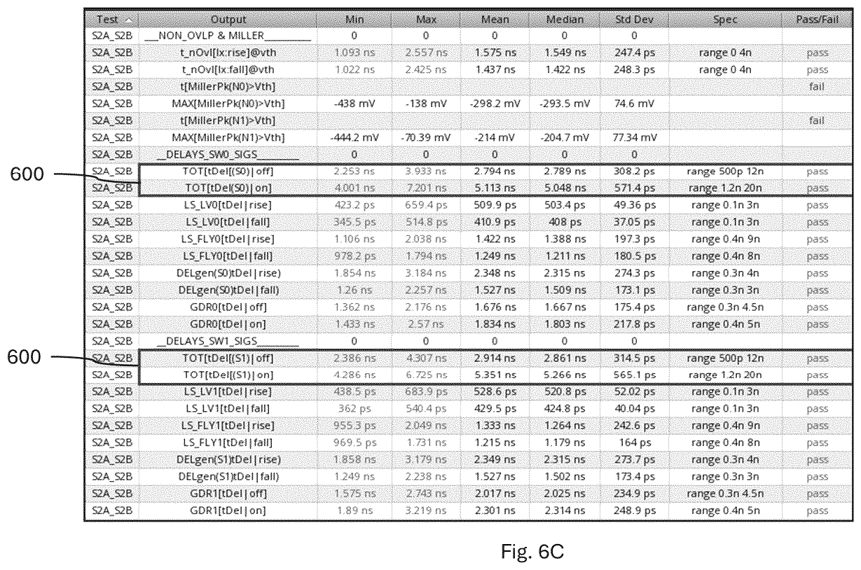

FIG. 6A is a table of parameters for Monte Carlo simulations of the circuit of FIG. 4, for non-overlapping functionality. 100 Monte-Carlo simulations were performed on a practical implementation of the circuit as shown in FIG. 4 with process, mismatch and parameter variation being performed. The following parameter variations were checked: input-voltage, battery voltage, core/rtc supply voltage and temperature. The range which was covered is shown in FIG. 6A.

FIG. 6B is a table of results for Monte Carlo simulations of the circuit of FIG. 4 having matching of delays, non-overlap time in the Monte Carlo simulation.

In FIG. 6B the differences of the delays (“D_dly”) are given for rising (“/”) and falling (“\”) edges in the 100 runs described before. The delta-delays at the 1.5V go inputs in the 1st line are absolute negligible. After the 1.5V to 5V level-shifters (output “D_dly(goS0_5V\:goS1_5V/)” and “D_dly(goS1_5V\:goS0_5V/)” and after the high-voltage level-shifters (outputs labelled by numeral 600) the delta delays are far below one 0.5 ns. Finally, the delays of the power gate drivers match well to the delay cells (outputs labelled by numeral 602). The last lines for S1 turn-on and S0 turn-on indicate that the percentage of non-overlapping time relative to the whole time for the entire turn-off/turn-on process rather short with around ⅓. Further reduction of the configurable matching delay seems to be possible here as the non-overlap time never goes to 0.

It should be noted the “S0” denotes the low side switch 106 and “S1” denotes the high side switch 104 in the tables.

FIG. 6C is a table of results for Monte Carlo simulations of the circuit of FIG. 4 having absolute delays in the Monte Carlo simulation. The non-overlap times are in lines 2 and 3.

It will be appreciated that in further embodiments, there may be more than two switches 104, 106 where the non-overlapping condition for more than two switches is desirable. For example, in some embodiments, there might be at least two switches in a non-overlapping condition plus diodes which provide further current paths when the switches are on.

Embodiments of the present disclosure provide a gate driver circuit that is easier to implement than known systems, requires less circuit area and/or has reduced current consumption when compared to known systems (for example, no DC current, and current consumption only when switching).

It will be appreciated that in further embodiments of the present disclosure, all or only some signals could be inverted and be low active. For example, G1 would be 0 in on state if switch 104 would be a p-MOS. Or go2 might be replaced by a low-active go2_n (go2—not) signal if GD2 and the Delay-generator of switch 106 would be inverting blocks.

It will be appreciated that embodiments of the present disclosure have primarily been described in relation to switches being implemented using MOS-power FETs. However, in further embodiments, the switches may be implemented using a different type of switch. For example, in high-voltage/high power applications IGBTs might be used as well. In further embodiments, switches may be implemented using GTOs and bipolars.

Embodiments of the present disclosure function such that the delay time introduced by the delay generator matches to the timing of the gate drivers in a way, that the non-overlap time is close to or slightly above zero.

Common reference numerals and variables between figures denote common features.

Various improvements and modifications can be made to the above without departing from the scope of the disclosure.

1. A gate driver circuit for a switching converter comprising a first switch and a second switch, the gate driver circuit comprising:
a first switch gate driver configured to:
receive a first control signal;
receive a first delay signal; and
provide a first switch gate drive signal to turn on the first switch when the first control signal and the first delay signal are both in a first state;
a second switch gate driver configured to:
receive a second control signal; and
provide a second switch gate drive signal to drive the switching operation of the second switch;
a first delay generator comprising:
a replica second switch gate driver; and
a first delay signal generator;
wherein:
the replica second switch gate driver is configured to provide a replica second switch gate drive signal to the first delay signal generator, the replica second switch gate drive signal being dependent on the first control signal; and
the first delay signal generator is configured to generate the first delay signal that is dependent on the replica second switch gate drive signal.

2. The gate driver circuit of claim 1, wherein the second switch gate driver and the replica second switch gate driver have substantially similar circuit topologies.

3. The gate driver circuit of claim 1, wherein:
the second switch gate driver comprises one or more second side transistors; and
the replica second switch gate driver comprises one or more replica second side transistors.

4. The gate driver circuit of claim 3, wherein:
a second switch driver transistor ratio is provided by:
a ratio of:
a transistor ratio of one of the one or more second side transistors to a transistor ratio of another of the one or more second side transistors; or
a transistor ratio of the second switch to the transistor ratio of one of the one or more second side transistors;
a replica second switch driver transistor ratio is provided by:
a ratio of:
a transistor ratio of one of the one or more replica second side transistors to a transistor ratio of another of the one or more replica second side transistors; or
a transistor ratio of a replica second switch to the transistor ratio of one of the one or more replica second side transistors; and
the second switch driver transistor ratio and the replica second switch driver transistor ratio are approximately equal.

5. The gate driver circuit of claim 4, wherein:
the transistor ratio of the one of the one or more second side transistors is the width to length ratio of the one of the one or more second side transistors;
the transistor ratio of the another of the one or more second side transistors is the width to length ratio of the another of the one or more second side transistors;
the transistor ratio of the second switch is the width to length ratio of the second switch;
the transistor ratio of the one of the one or more replica second side transistors is the width to length ratio of the one of the one or more replica second side transistors;
the transistor ratio of the another of the one or more replica second side transistors is the width to length ratio of the another of the one or more replica second side transistors; and
the transistor ratio of the replica second switch is the width to length ratio of the replica second switch.

6. The gate driver circuit of claim 1, wherein:
the second switch gate driver comprises one or more second side logic gates and the replica second switch gate driver comprises one or more replica second side logic gates that are the same type as the one or more second side logic gates.

7. The gate driver circuit of claim 1, wherein:
the second switch gate driver is positioned sufficiently close to the replica second switch gate driver to be subject to a substantially similar operating temperature during operation.

8. The gate driver circuit of claim 1, wherein the second switch gate driver comprises:
a first gate driver switch;
a second gate driver switch coupled to the first gate driver switch at a second switch gate driver output node, a second switch gate driving signal being provided from the second switch gate driver output node;
a first driving circuit for driving the switching of the first gate driver switch; and
a second driving circuit for driving the switching of the second gate driver switch.

9. The gate driver circuit of claim 8, wherein:
the first driving circuit comprises a first buffer circuit and a first NAND gate; and
the second driving circuit comprises a second buffer circuit and a third buffer circuit or an AND circuit.

10. The gate driver circuit of claim 8, wherein the replica second switch gate driver comprises:
a first delay generator switch;
a second delay generator switch coupled to the first delay generator switch at a replica second switch gate driver output node, the replica second switch gate drive signal being provided from the replica second switch gate driver output node;
a replica first driving circuit for driving the switching operation of the first delay generator switch; and
a replica second driving circuit for driving the switching operation of the second delay generator switch.

11. The gate driver circuit of claim 10, wherein:
the replica first driving circuit comprises:
a second NAND gate;
a first inverter circuit; and
a second inverter circuit
the replica second driving circuit comprises:
a third NAND gate; and
a third inverter circuit.

12. The gate driver circuit of claim 10, further comprising a programmable delay circuit configured to:
receive a first delay generator switch indicator signal from the replica first driving circuit;
apply a delay parameter to the first delay generator switch indicator signal; and
provide the first delay generator switch indicator signal, after the delay parameter has been applied, to the replica second driving circuit;
wherein the replica second driving circuit is configured to provide a delayed gate driving signal to the second delay generator switch that is dependent on the first control signal and the first delay generator switch indicator signal after the delay parameter has been applied.

13. The gate driver circuit of claim 12, wherein the programmable delay circuit is configured to receive a configuration signal, the delay parameter being dependent on the configuration signal.

14. The gate driver circuit of claim 13, further comprising:
a first level shifter configured to level shift the first control signal; and
a second level shifter configured to provide the configuration signal to the first delay generator to correct for a switch delay resulting from the first level shifter.

15. The gate driver circuit of claim 10, wherein the first delay signal generator comprises:
a third delay generator switch;
a fourth delay generator switch coupled to the third delay generator switch at a first node, the fourth delay generator switch comprising a fourth delay generator switch gate terminal coupled to the replica second switch gate driver output node; and
a delay signal generator buffer circuit comprising:
a first input terminal coupled to the first node; and
a first output terminal for providing the first delay signal.

16. The gate driver circuit of claim 15, wherein the third delay generator switch is driven by fewer inverter stages than the fourth delay generator switch.

17. The gate driver circuit of claim 15, wherein the first switch and the fourth delay generator switch have one or more of:
the same transistor type; and/or
approximately equal transistor widths and/or lengths.

18. The gate driver circuit of claim 15, further comprising:
a fourth buffer circuit configured to receive the first control signal and to provide a first replica control signal; and
a fourth inverter circuit configured to receive the first replica control signal and to provide a second replica control signal;
wherein:
the replica first driving circuit is configured to receive the second replica control signal, and to drive the switching operation of the first delay generator switch based on the second replica control signal and a second delay generator switch indicator signal.

19. The gate driver circuit of claim 18, wherein the third delay generator switch comprises a third delay generator switch gate terminal configured to receive the second replica control signal.

20. The gate driver circuit of claim 1, wherein the first state is an on state.

21. The gate driver circuit of claim 1, wherein:
the first switch is a high side switch and the second switch is a low side switch; and/or
the first switch is the low side switch and the second switch is the high side switch.

22. The gate driver circuit of claim 1, wherein:
the second switch gate driver is configured to:
receive a second delay signal; and
provide the second switch gate drive signal to turn on the second switch when the second control signal and the second delay signal are both in the first state or a second state;
the gate driver circuit comprises:
a second delay generator comprising:
a replica first switch gate driver; and
a second delay signal generator; wherein:
the replica first switch gate driver is configured to provide a replica first switch gate drive signal to the second delay signal generator, the replica first switch gate drive signal being dependent on the second control signal; and
the second delay signal generator is configured to generate the second delay signal that is dependent on the replica first switch gate drive signal.

23. A method of providing a gate driver circuit for a switching converter comprising a first switch and a second switch, the gate driver circuit comprising:
a first switch gate driver configured to:
receive a first control signal;
receive a first delay signal; and
provide a first switch gate drive signal to turn on the first switch when the first control signal and the first delay signal are both in a first state;
a second switch gate driver configured to:
receive a second control signal; and
provide a second switch gate drive signal to drive the switching operation of the second switch;
a first delay generator comprising:
a replica second switch gate driver; and
a first delay signal generator;
wherein:
the replica second switch gate driver is configured to provide a replica second switch gate drive signal to the first delay signal generator, the replica second switch gate drive signal being dependent on the first control signal; and
the first delay signal generator is configured to generate the first delay signal that is dependent on the replica second switch gate drive signal.
